(19) United States
(12) Patent Application Publication
(10) Pub. No.: US 2014/0174497 A1
(43) Pub. Date: Jun. 26, 2014

(54) PACKING OF SOLAR CELL WAFERS

(71) Applicants: Xiuwen TU, San Jose, CA (US); Asnat MASAD, Cupertino, CA (US)

(72) Inventors: Xiuwen TU, San Jose, CA (US); Asnat MASAD, Cupertino, CA (US)

(21) Appl. No.: 13/725,663

(22) Filed: Dec. 21, 2012

(51) Int. Cl. H01L 31/05; H01L 31/18

(52) U.S. Cl. CPC H01L 31/05; H01L 22/10; H01L 31/18
USPC 136/244; 438/15; 438/66

(57) ABSTRACT

Solar cell wafers are fabricated, tested, and sorted into solar cell wafer stacks. A solar cell wafer stack includes a solar cell wafer with a front side that faces a front side of an adjacent solar cell wafer, and another solar cell wafer with a backside that directly contacts a backside of the solar cell wafer. A front side protector may be placed between front sides of adjacent solar cell wafers. The solar cell wafer stack includes end pieces on both ends, and is wrapped to hold and bundle the solar cell wafers, front side protectors, and end pieces together as a single unit. The solar cell wafer stack is boxed along with other solar cell wafer stacks, and then transported to another location where the solar cell wafers are assembled into solar cell modules.

### TECHNICAL FIELD

Embodiments of the subject matter described herein relate generally to solar cells. More particularly, embodiments of the subject matter relate to solar cell manufacturing.

### BACKGROUND

Solar cells are well known devices for converting solar radiation to electrical energy. A solar cell has a front side that faces the sun during normal operation to collect solar radiation and a backside opposite the front side. Solar radiation impinging on the solar cell creates electrical charges that may be harnessed to power an external electrical circuit, such as a load.

A solar cell module comprises a plurality of solar cells that are electrically connected together. The solar cell module includes a frame and other components that protect the solar cells and allow the solar cells to be installed in the field, such as a rooftop, for example. For cost, logistics, and other reasons, the solar cells may be fabricated in one location and assembled into solar cell modules in another location. In that case, the solar cells may be stacked one on top of another, with a piece of paper between a front side of a solar cell and a backside of an adjacent solar cell. The stacked solar cells are then shrink wrapped, placed in foam inserts, and then boxed for shipping to the location where solar cell module assembly is performed.

### BRIEF SUMMARY

In one embodiment, solar cell wafers are fabricated, tested, and sorted into solar cell wafer stacks. A solar cell wafer stack includes a solar cell wafer with a front side that faces a front side of an adjacent solar cell wafer, and another solar cell wafer with a backside that directly contacts a backside of the solar cell wafer. A front side protector may be placed between front sides of adjacent solar cell wafers. The solar cell wafer stack includes end pieces on both ends, and is wrapped to hold and bundle the solar cell wafers, front side protectors, and end pieces together as a single unit. The solar cell wafer stack is boxed along with other solar cell wafer stacks, and then transported to another location where the solar cell wafers are assembled into solar cell modules.

These and other features of the present invention will be readily apparent to persons of ordinary skill in the art upon reading the entirety of this disclosure, which includes the accompanying drawings and claims.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures. The figures are not drawn to scale.

FIG. 1 shows a flow diagram of a method of manufacturing a solar cell module in accordance with an embodiment of present invention.

FIG. 2 shows a solar cell wafer in accordance with an embodiment of the present invention.

FIG. 3 shows an exploded view of a solar cell wafer stack in accordance with an embodiment of the present invention.

FIG. 4 shows an example pseudo-square shape.

FIG. 5 shows a wrapped solar cell wafer stack in accordance with an embodiment of the present invention.

FIG. 6 shows an exploded view of a solar cell wafer stack in accordance with another embodiment of the present invention.

FIG. 7 shows a wrapped solar cell wafer stack in accordance with another embodiment of the present invention.

FIG. 8 graphically illustrates the boxing of solar cell wafer stacks in accordance with an embodiment of the present invention.

FIG. 9 shows a solar cell module manufactured in accordance with an embodiment of the present invention.

FIG. 10 shows a flow diagram of a method of manufacturing solar cell modules in accordance with an embodiment of the present invention.

### DETAILED DESCRIPTION

In the present disclosure, numerous specific details are provided, such as examples of apparatus, components, and methods, to provide a thorough understanding of embodiments of the invention. Persons of ordinary skill in the art will recognize, however, that the invention can be practiced without one or more of the specific details. In other instances, well-known details are not shown or described to avoid obscuring aspects of the invention.

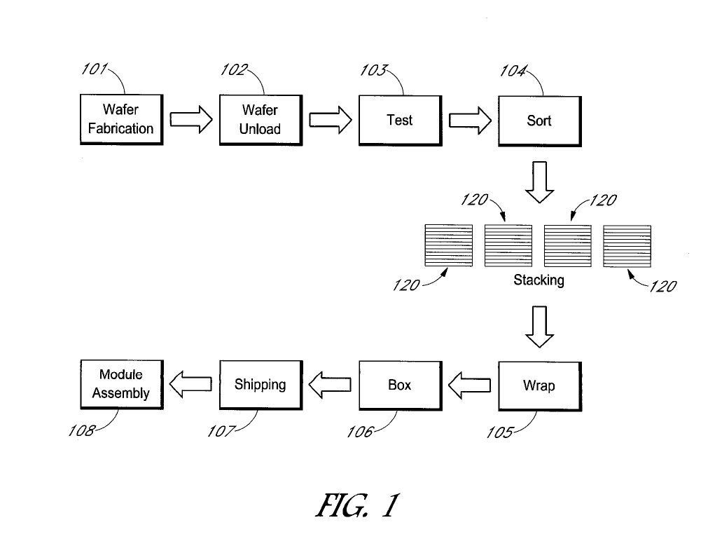

FIG. 1 shows a flow diagram of a method of manufacturing a solar cell module in accordance with an embodiment of present invention. In the example of FIG. 1, the method includes fabrication of the solar cells in one location and assembly of the solar cells into solar cell modules in another location. More specifically, the manufacturing steps 101-106 may be performed in one factory, and the manufacturing step 108 may be performed in another factory. The factories are in different locations, necessitating packing of the solar cells for shipping from one factory to the other.

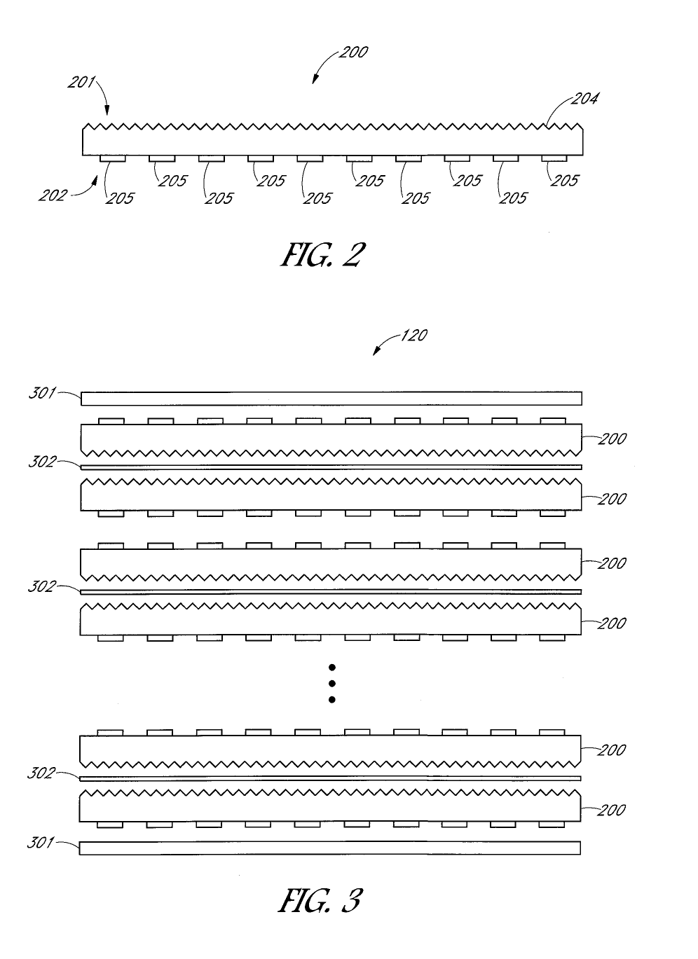

In one embodiment, the solar cells are in the form of solar cell wafers (see FIG. 2, solar cell wafer 200). The solar cell wafers are fabricated as complete solar cells (step 101), including diffusion regions and metal contacts electrically connected to the diffusion regions. In the factory, the solar cell wafers may be carried in wafer cassettes. After fabrication, solar cell wafers may be unloaded from a wafer cassette (step 102) and onto a transfer station before being transferred to a test station for testing (step 103).

For example, a wafer cassette containing a plurality of wafers may be placed on an elevator. A robotic arm may push a solar cell wafer from its slot in the wafer cassette toward the transfer station. The solar cell wafer may then be transferred from the transfer station to the test station by a walking beam, pick and place robot, or other wafer moving means. Thereafter, the wafer cassette may be raised or lowered by the elevator to allow the robot arm to push another solar cell wafer from the wafer cassette toward the transfer station to continue the unloading the process.

At the test station, the solar cell wafers are tested for basic functionality and to determine their electrical characteristics (step 103). For example, the current-voltage (I-V) characteristics of each solar cell wafer may be measured at the test station. After testing, a sorting machine sorts the solar cell wafers into solar cell wafer stacks 120 (step 104). In one embodiment, the solar cell wafers are stacked according to their test results in a sorting process known as “binning.” A solar cell wafer stack 120 may thus comprise solar cell wafers with the same or similar electrical characteristics. The stacking of the solar cell wafers may be performed by the sorting machine or a separate stacking mechanism.

As will be more apparent below, solar cell wafers in a solar cell wafer stack 120 may be arranged such that a front side of a solar cell wafer faces a front side of an adjacent solar cell wafer, and a backside of a solar cell wafer faces a backside of an adjacent solar cell wafer. In one embodiment, a front side protector is placed between front sides of adjacent solar cells and no front side protector is placed between backsides of adjoining solar cell wafers. In another embodiment, no front side protector is placed between front sides and between backsides of solar cell wafers.

Each solar cell wafer stack 120 is wrapped to hold and bundle the solar cell wafers together as a single unit (step 105). In one embodiment, a solar cell wafer stack 120 is shrink-wrapped for a form fitting wrapping. The wrapped solar cell wafer stacks 120 are then boxed with protective inserts (step 106) and shipped to the next factory (step 107), where the solar cell wafers are assembled into solar cell modules (108). As can be appreciated, one or more of the wrapping, boxing, and shipping steps may be omitted depending on the location where the solar cell modules are assembled. For example, the wafer stacks 120 do not need to be wrapped and may simply be transported by cart, conveyor, or other local transport mechanism when module assembly is in the same general area where the solar cell wafers are fabricated.

FIG. 2 shows a solar cell wafer 200 in accordance with an embodiment of the present invention. The solar cell wafer 200 has a front side (see arrow 201) that faces the sun to collect solar radiation during normal operation. The front side surface of the solar cell wafer 200 may be textured (see 204) for improved solar radiation collection. The solar cell wafer 200 has a backside (see arrow 202) opposite the front side. The solar cell wafer 200 is an all backside contact solar cell in that all of the metal contacts 205 are on the backside. There are no metal contacts on the front side of the solar cell wafer 200 in this example. The metal contacts 205 are electrically connected to diffusion regions, all of which are also formed on the backside. That is, no metal contact 205 electrically connects to a doped or diffusion region on the front side; accordingly, a metal contact 205 does not go through the bulk of the solar cell wafer 200.

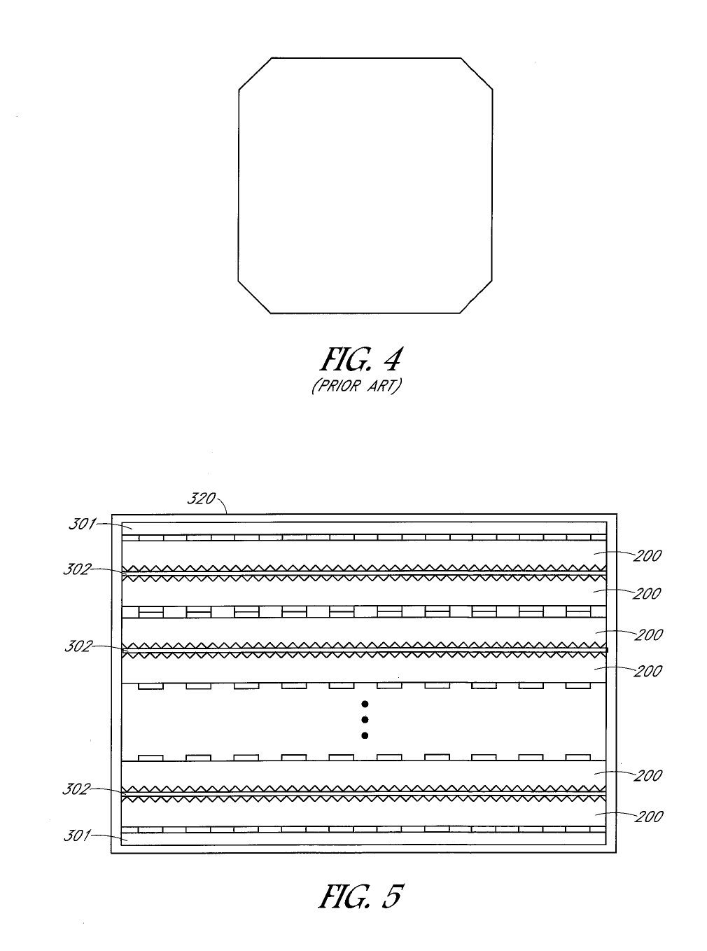

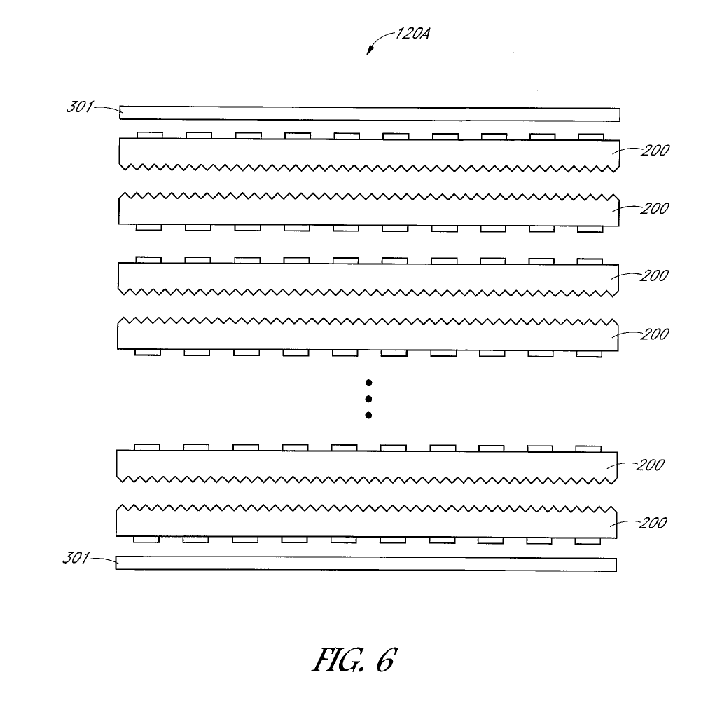

FIG. 3 shows an exploded view of a solar cell wafer stack 120 in accordance with an embodiment of the present invention. In the example of FIG. 3, the solar cell wafer stack 120 comprises end protectors 301, solar cell wafers 200, and front side protectors 302. In one embodiment, the end protectors 301, solar cell wafers 200, and front side protectors 302 have substantially the same shape and dimensions. For example, the end protectors 301, solar cell wafers 200, and front side protectors 302 may all substantially have the same dimensions, and all have a pseudo-square shape, such as the pseudo-square shape shown in FIG. 4. In one embodiment, each solar cell wafer stack 120 has 150 solar cell wafers 200.

As their name implies, the end protectors 301 protect the top end and the bottom end of a solar cell wafer stack 120. In one embodiment, an end protector 301 comprises a piece of cardboard that has been cut to have substantially the same shape and dimensions as a solar cell wafer 200. The end protectors 301 protect the solar cell wafer stack 120 by covering the exposed sides of solar cell wafers 200 at the ends and providing shock protection during transport and handling.

A front side protector 302 protects the front side of a solar cell wafer 200. This is particularly important in backside contact solar cells because the metal contacts 205 of one solar cell wafer 200 may scratch the front side surface of an adjoining solar cell wafer 200. In one embodiment, a front side protector 302 comprises a piece of paper that has been cut to have substantially the same shape and dimensions as a solar cell wafer 200.

In the example of FIG. 3, a front side protector 302 is placed between front sides of adjacent solar cell wafers 200. This prevents the front side of a solar cell wafer 200 from directly contacting the front side of the next solar cell wafer 200. To save on the number of front side protectors 302 employed, no front side protector 302 is placed between backsides of adjoining solar cell wafers 200. That is, the backside of one solar cell wafer 200 directly contacts the backside of an adjoining solar cell wafer 200.

FIG. 5 shows a wrapped solar cell wafer stack 120 in accordance with an embodiment of the present invention. In the example of FIG. 5, a wrapper 320 is shrunk to tightly form fit to the solar cell wafer stack 120. The wrapper 320 holds and bundles the end protectors 301, front side protectors 302, and solar cell wafers 200 together as a single unit, allowing for ease of handling and transport.

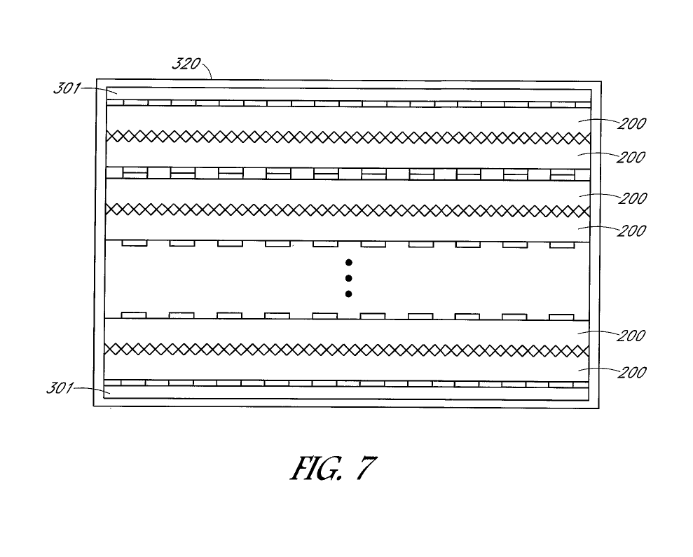

FIG. 6 shows an exploded view of a solar cell wafer stack 120A in accordance with another embodiment of the present invention. In the example of FIG. 6, the solar cell wafer stack 120A comprises the end protectors 301 and the solar cell wafers 200. The solar cell wafer stack 120A is the same as the previously described solar cell wafer stack 120 except for the absence of front side protectors 302. In the solar cell wafer stack 120A, the front sides of adjoining solar cell wafers 200 face each other, and the backsides of adjoining solar cell wafers 200 face each other. In contrast to a solar cell wafer stack 120, there is no front side protector 302 between front sides of adjoining solar cell wafers 200 in the solar cell wafer stack 120A. That is, in the solar cell wafer stack 120A, the front side of a solar cell wafer 200 directly contacts the front side of the adjoining solar cell wafer 200. Unlike the backside of a solar cell wafer 200, which has metal contacts, the front side of the solar cell wafer 200 does not have metals or other abrasive protrusions that may damage the front side of an adjoining solar cell wafer 200. Therefore, facing the front sides of adjoining solar cell wafers 200 toward each other without a front side protector 302 may be done in some backside contact solar cell designs.

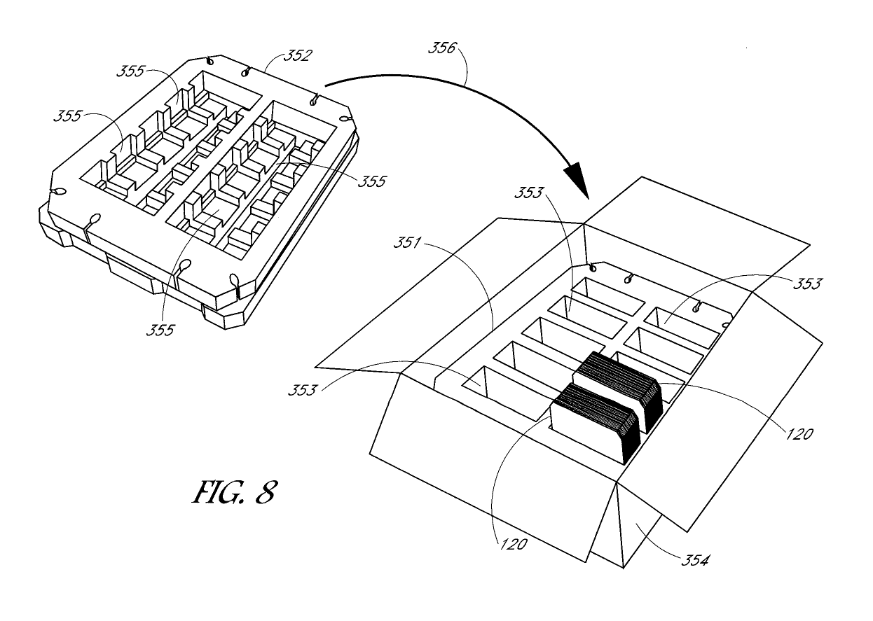

FIG. 7 shows the solar cell wafer stack 120A as shrink-wrapped by the wrapper 320 in accordance with an embodiment of the present invention.

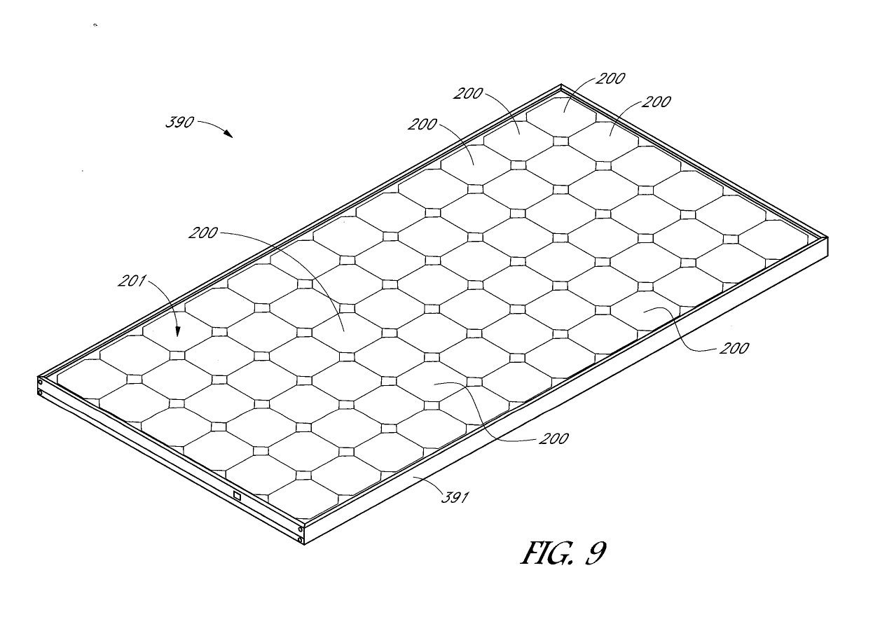

FIG. 8 graphically illustrates the boxing of solar cell wafer stacks in accordance with an embodiment of the present invention. In the example of FIG. 8, each solar cell wafer stack 120 is inserted into a slot 353 of an insert 351. After filling the slots 353 with solar cell wafer stacks 120, an insert 352 is placed over the insert 351 such that the solar cell wafer stacks 120 go into corresponding slots 355 of the insert 352. The slots 353 and 355 may have a minimalist design to cut down on shipping weight and the amount of material needed to make the inserts. Note that only some of the inserts 353 and 355 are labeled in FIG. 8 for clarity of the illustration.

In one embodiment, the inserts 351 and 352 comprise foam inserts. The insert 351 may be a mirror image of the insert 352. The slots 355 and 353 line up to snugly hold the solar cell wafer stacks 120, thereby preventing movement and providing shock protection during shipping. The insert 351 may be placed in a packaging box 354, filled with solar cell wafer stacks 120, and then covered with the insert 352. Thereafter, the packaging box 354 is closed and prepared for shipping.

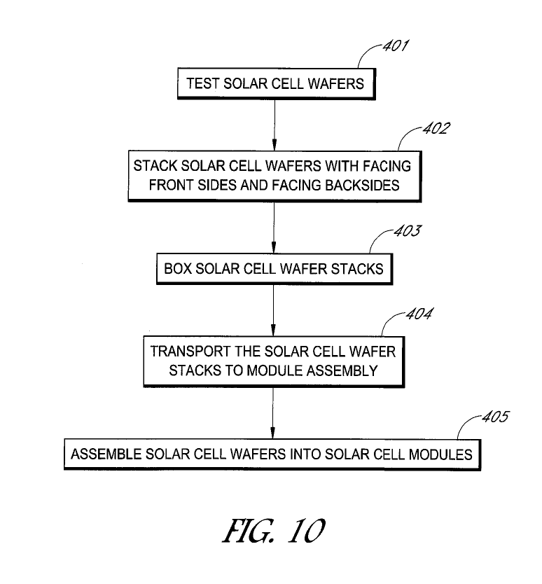

FIG. 9 shows a solar cell module 390 manufactured in accordance with an embodiment of the present invention. Upon arrival in the location where solar cell modules are assembled, the solar cell wafer stacks 120 are unloaded from the packaging box 354. Solar cell wafers 200 are removed from the solar cell wafer stacks 120, serially connected, and then formed in a protective package comprising glass, encapsulant, and backsheet. The protective package is mounted on a frame 391. Note that only some of the solar cell wafers 200 are shown in FIG. 9 for clarity of illustration. The front sides of the solar cell wafers 200 (see arrow 201) are visible in FIG. 9. As installed in the field, the solar cell module 390 is oriented such that the front sides of the solar cell wafers 200 are facing the sun during normal operation.

FIG. 10 shows a flow diagram of a method of manufacturing solar cell modules in accordance with an embodiment of the present invention. In the example of FIG. 10, solar cell wafers are tested (step 401). After testing, the solar cell wafers are sorted into stacks of solar cell wafers (step 402). A solar cell wafer stack may comprise a plurality of tested solar cell wafers that are arranged such that a front side of a first solar cell wafer is facing a front side of a second adjacent solar cell and a backside of the first solar cell wafer is directly contacting a backside of a third adjoining solar cell wafer. A backside of a fourth solar cell wafer that is adjoining the second solar cell wafer is directly contacting a backside of the second solar cell wafer, and so on. In one embodiment, a front side protector may be placed between front sides of adjacent solar cells. In another embodiment, the front sides of adjoining solar cells are directly contacting. The solar cell wafer stacks are thereafter boxed (step 403), such as by placing them into slots of a pair of inserts, and placing the inserts in a packaging box. The solar cell wafer stacks are transported to the location where module assembly is performed (step 404). There, the solar cell wafers are assembled into solar cell modules (step 405).

Solar cell manufacturing processes and structures have been disclosed. While specific embodiments of the present invention have been provided, it is to be understood that these embodiments are for illustration purposes and not limiting. Many additional embodiments will be apparent to persons of ordinary skill in the art reading this disclosure.

What is claimed is:

1. A method comprising:
testing a plurality of solar cell wafers;
after testing the plurality of solar cell wafers, stacking the plurality of solar wafers into a solar cell wafer stack, the plurality of solar cell wafers in the solar cell wafer stack being arranged such that a front side of a first solar cell wafer is facing toward a front side of an adjacent second solar cell wafer, and a backside of the first solar cell wafer is directly contacting a backside of an adjoining third solar cell wafer; and
boxing the solar cell wafer stack along with other solar cell wafer stacks.

2. The method of claim 1 wherein the front side of the first solar cell wafer directly contacts the front side of the adjacent second solar cell wafer.

3. The method of claim 1 further comprising:
placing a front side protector between the front side of the first solar cell wafer and the front side of the adjacent second solar cell wafer.

4. The method of claim 3 wherein the front side protector has a same shape and dimension as the plurality of solar cell wafers.

5. The method of claim 3 wherein the front side protector has a pseudo-square shape.

6. The method of claim 1 wherein stacking the plurality of solar wafers into the solar cell wafer stack further comprises placing end protectors on each end of the solar cell wafer stack.

7. The method of claim 6 wherein the end protectors have a same shape and dimensions as the plurality of solar cell wafers.

8. The method of claim 1 further comprising wrapping the solar cell wafer stack.

9. The method of claim 1 further comprising:
shipping the solar cell wafer stack to a module assembly location; and
assembling the solar cell wafers of the solar cell wafer stack into a solar cell module.

10. An article of manufacture comprising:
a stack of solar cell wafers comprising a first solar cell wafer having a front side that faces a front side of a second solar cell wafer that is adjacent to the first solar cell wafer, a third solar cell wafer having a backside that directly contacts a backside of the first solar cell wafer, and a fourth solar cell wafer having a backside that directly contacts a backside of the second solar cell wafer.

11. The article of manufacture of claim 10 wherein the front side of the first solar cell wafer directly contacts the front side of the second solar cell wafer.

12. The article of manufacture of claim 10 further comprising:
a front side protector between the front side of the first solar cell wafer and the front side of the second solar cell wafer.

13. The article of manufacture of claim 12 wherein the front side protector has a same shape and dimension as the solar cell wafers.

14. The article of manufacture of claim 12 wherein the front side protector has a pseudo-square shape.

15. The article of manufacture of claim 10 further comprising an end protector on an end of the solar cell wafer stack.

16. The article of manufacture of claim 10 further comprising a wrapper wrapping the solar cell wafer stack.

17. A method of comprising:
stacking a plurality of solar cell wafers into a solar cell wafer stack such that a front side of a first solar cell wafer faces a front side of a second solar cell wafer that is adjacent to the first solar cell wafer, a backside of a third solar cell directly contacts a backside of the first solar cell wafer, and a backside of a fourth solar cell directly contacts a backside of the second solar cell wafer; and
wrapping the solar cell wafer stack.

18. The method of claim 17 wherein wrapping the solar cell wafer stack comprises shrink wrapping the solar cell wafer stack.

19. The method of claim 18 wherein stacking the plurality of solar cell wafers into the solar cell wafer stack comprises placing an end protector on an end of the solar cell wafer stack.

20. The method of claim 19 wherein stacking the plurality solar cell wafers into the solar cell wafer stack comprises placing a front side protector between the front sides of the first and second solar cell wafers.
